(19) United States
(12) Patent Application Publication
(10) Pub. No.: US 2025/0293111 A1
(43) Pub. Date: Sep. 18, 2025

(54) LID THROUGH INTERPOSER OF SEMICONDUCTOR PACKAGE FOR THERMAL MANAGEMENT

(71) Applicant: QUALCOMM Incorporated, San Diego, CA (US)

(72) Inventors: Yujen CHEN, Taichung (TW); Aniket PATIL, San Diego, CA (US); Yangyang SUN, San Diego, CA (US); Bohan YAN, San Diego, CA (US)

(21) Appl. No.: 18/603,668

(22) Filed: Mar. 13, 2024

(51) Int. Cl. H01L 23/367; H01L 23/00; H01L 25/00; H01L 25/18; H10B 80/00

(52) U.S. Cl. CPC H01L 23/3675; H01L 24/32; H01L 25/18; H01L 25/50; H10B 80/00; H01L 2224/32245

(57) ABSTRACT

Disclosed are semiconductor packages in which a heat producing die, such as a system-on-chip (SoC) die is encapsulated in a mold between a substrate and an interposer. To help dissipate heat generated by the die, a thermally conductive lid is formed to conduct heat from the die. The lid is formed through the interposer to where it can be thermally coupled with a heat sink. In this way, the heat from the die can be conducted away.

### BACKGROUND OF THE DISCLOSURE

### 1. Field of the Disclosure

This disclosure relates generally to die packages or modules, and more specifically, but not exclusively, to semiconductor packages/modules that include a lid through an interposer for thermal management and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/modules, RFIC chips such as switches (SW), low noise amplifiers (LNA), power amplifiers (PA), digital amplifiers (DA), filters, etc. are placed side-by-side in a package, e.g., for an RF frontend module. Also, system-on-chip (SoC) dies with multiple cores and processors that perform a wide range of functions are prevalent. Unfortunately, some of the chips or dies generate significant amount of heat during their operation, which can be damaging. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a die on an upper surface of a substrate. The semiconductor package may also comprise an interposer above the die. The semiconductor package may further comprise a mold between the substrate and the interposer. The mold may encapsulate sides of the die. The semiconductor package may yet comprise a lid thermally coupled with the die. The lid may comprise a lateral portion and two side portions forming a ‘U’ shape. The lateral portion of the lid may be between the die and the interposer. The side portions of the lid may extend through and above the interposer.

A method of fabricating an exemplary semiconductor package is disclosed. The method may comprise providing a die on an upper surface of a substrate. The method may also comprise forming an interposer above the die. The method may comprise forming a mold between the substrate and the interposer. The mold may encapsulate sides of the die. The method may comprise forming a lid thermally coupled with the die. The lid may comprise a lateral portion and two side portions forming a ‘U’ shape. The lateral portion of the lid may be between the die and the interposer. The side portions of the lid may extend through and above the interposer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a cross section of an example of a conventional semiconductor package.

FIG. 1B a top view of the conventional semiconductor package portion of FIG. 1A.

FIG. 2A illustrates a cross section of an example of a semiconductor package in accordance with one or more aspects of the disclosure.

FIG. 2B a top view of the example semiconductor package portion of FIG. 2A.

FIG. 2C illustrates a perspective view of a thermal lid in accordance with one or more aspects of the disclosure.

FIGS. 3A-3D illustrate examples of stages of fabricating a semiconductor package in accordance with one or more aspects of the disclosure.

FIGS. 4-5 illustrate flow charts of example methods of manufacturing a semiconductor package in accordance with at one or more aspects of the disclosure.

FIG. 6 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a die, an interposer, a mold and a lid. The die may be on an upper surface of a substrate. The interposer may be formed above the die. The mold may be formed between the substrate and the interposer. The mold may encapsulate sides of the die. The lid may be thermally coupled with the die. The lid may comprise a lateral portion and two side portions forming a ‘U’ shape. The lateral portion of the lid may be between the die and the interposer, and the side portions of the lid may extend through and above the interposer. The lid may allow more heat to be carried away from the die.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

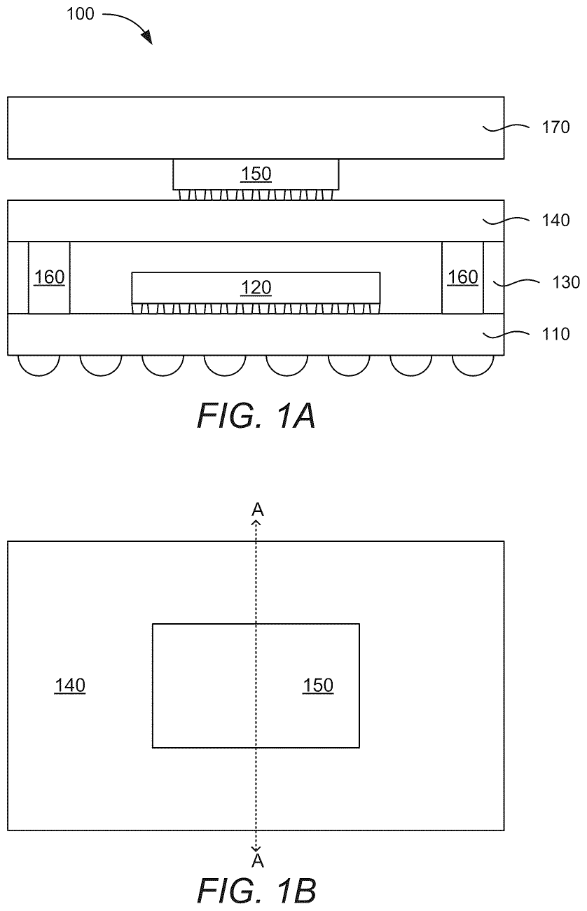

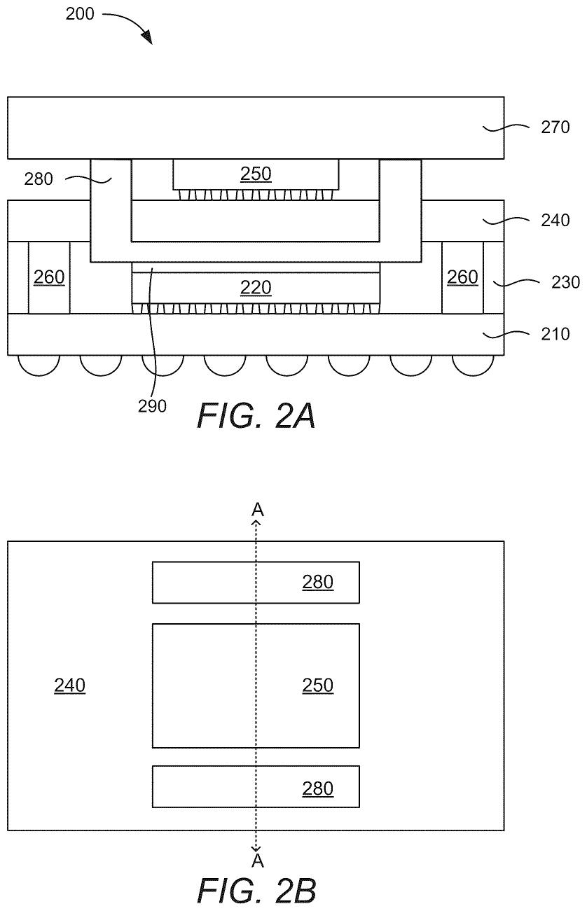

As indicated above, some chips or dies of a semiconductor package may generate a significant amount of heat that needs to be removed for proper operation of the semiconductor package. FIG. 1A illustrates an example of a conventional semiconductor package 100. FIG. 1B illustrates a top view of the conventional semiconductor package 100 below the heat sink 170. The cross section illustrated in FIG. 1A corresponds to the cross section along the line A-A in FIG. 1B.

The semiconductor package 100 may also be referred as a molded embedded package (MEP). The semiconductor package 100 includes a first die 120 provided on a substrate 110, an interposer 140 above the first die 120, a mold 230 between the substrate 210 and the interposer 140, a second die 150 provided on the interposer 140, one or more through-mold vias 160, and a heat sink 170.

Thermal considerations can become a challenge in MEP products. For example, it can be challenging to remove heat generated by the first die 120. With the conventional semiconductor package 100, heat generated by the first die 120 must be conducted away below through the substrate 110 and above through the mold 130 and the interposer 140. If the first die 120 is a die that can generate significant amount of heat (e.g., system-on-chip (SoC)), this can become problematic.

To address these and other issues of the conventional semiconductor package, it is proposed to provide an increased heat removing capability by providing a thermally conductive path from the heat generating dies. The generated heat may be conducted away to a heat sink for example.

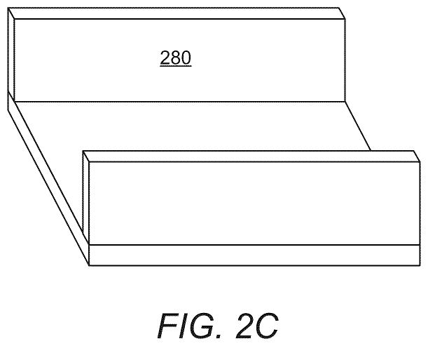

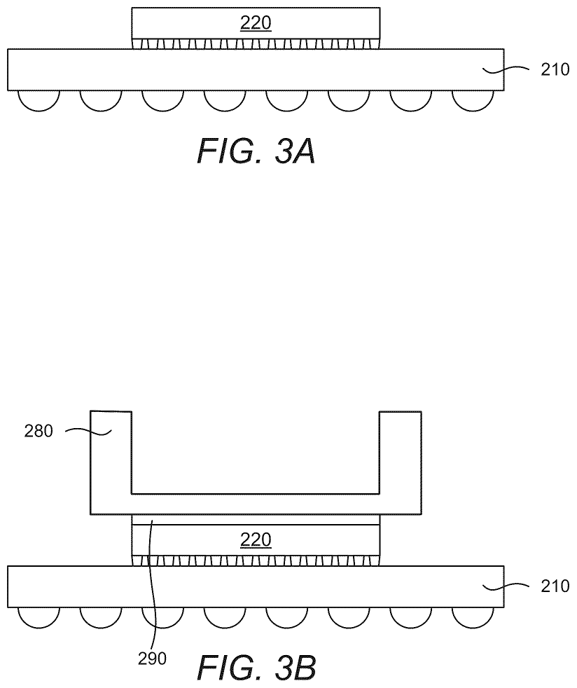

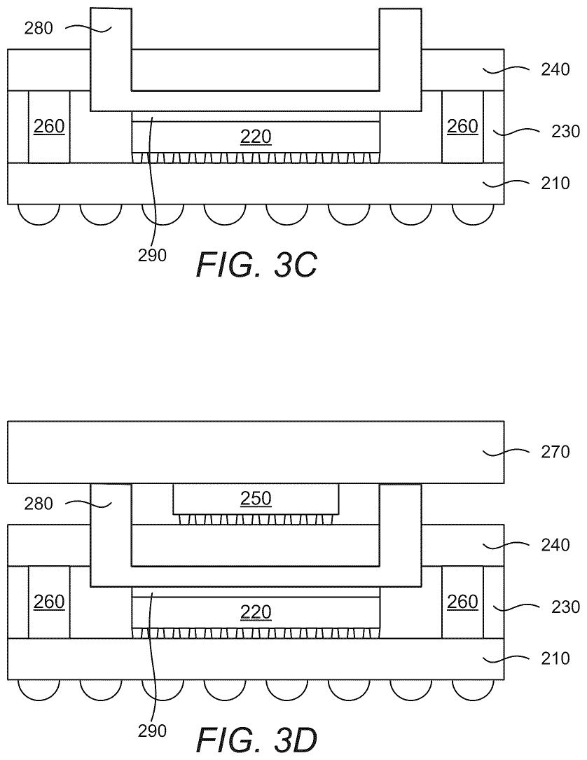

This is illustrated in FIGS. 2A-2C. FIG. 2A illustrates an example of a semiconductor package 200 in accordance with one or more aspects of the disclosure. FIG. 2B illustrates a top view of the semiconductor package 200 below the heat sink 270. The cross section illustrated in FIG. 2A may correspond to the cross section along the line A-A in FIG. 2B. In an aspect, the semiconductor package 200 may be an MEP package.

The semiconductor package 200 may include a die 220 on an upper surface of a substrate 210. The die 220 may be a heat generating die 220, such as a system-on-chip (SoC) die, which may include cores, central processing units (CPU), graphic processing units (GPU), tensor processing units (TPU), etc.

The semiconductor package 200 may also include an interposer 240 above the die 220, and a mold 230 between the substrate 210 and the interposer 240. The mold 230 may encapsulate sides of the die 220.

To efficiently conduct heat away from the die 220, the semiconductor package 200 may also include a lid 280 thermally coupled with the die 220. The lid 280 may be formed from metal such as copper (Cu). The lid 280 may comprise a lateral portion and two side portions forming a ‘U’ shape. The lateral portion of the lid 280 may be between the die 220 and the interposer 240. The side portions of the lid 280 may extend through and above the interposer 240.

Note that the lateral portion of the lid 280 may be in direct contact with an upper surface of the die 220. This is one way that thermal coupling may occur between the die 220 and the lid 280.

But as seen in FIG. 2A, a thermal interface material (TIM) 290 may be formed between the die 220 and the lateral portion of the lid 280 to facilitate heat transfer from the die 220 to the lid 280. An upper surface of the TIM 290 may be in direct contact with a lower surface of the lateral portion of the lid 280. Alternatively or in addition thereto, a lower surface of the TIM 290 is in direct contact with an upper surface of the die 220. Examples of TIM may include thermal tapes, greases, gels, adhesives, dielectric pads, phase change materials, and graphites.

The semiconductor package 200 may further include a heat sink 270 on the lid 280 above the interposer. The heat sink 270, which may be a system-wide heat sink, may be thermally coupled with upper surfaces of the side portions of the lid 280. For example, the heat sink 270 may be in direct contact with the upper surfaces of the side portions of the lid 280.

The semiconductor package 200 may include multiple dies. In this instance, the die 220 may be referred to as the first die 220. The semiconductor package 200 may also include at least a second die 250 provided on an upper surface of the interposer 240, in between the side portions of the lid 280. In an aspect, the second die 250 may be a memory die. In another aspect, the heat sink 270 may be thermally coupled to the second die 250, e.g., may be in direct contact with an upper surface of the second die 250.

To enable communication between the first die 220 and the second die 250, one or more through-mold vias 260 (e.g., from metals such as copper) may be formed between the substrate 210 and the interposer. While not shown, the substrate 210 may comprise one or more redistribution layers (RDL). Alternatively or in addition thereto, the interposer 240 may also comprise one or more RDLs. In this way, electrical signals may be exchanged between the first die 220 and the second die 250 through the substrate 210, the one or more through-mold vias 260, and the interposer 240.

As mentioned, FIG. 2B illustrates a top view of the semiconductor package 200 below the heat sink 270. Note that there may be side portions of the lid 280 on two sides, e.g., upper and lower, but not on other two sides, e.g., left and right. This is so that there can sufficient room so that signals from/to the second die 250 may be routed, e.g., to the one or more through-mold vias 260.

FIG. 2C illustrates a perspective view of the lid 280, which may also be referred to as a thermal lid 280, in accordance with one or more aspects of the disclosure. As seen, the side portions of the lid 280 does not block all sides. Again, in an aspect, routing of signals to/from the second die 250 can be allowed by such design of the lid 280.

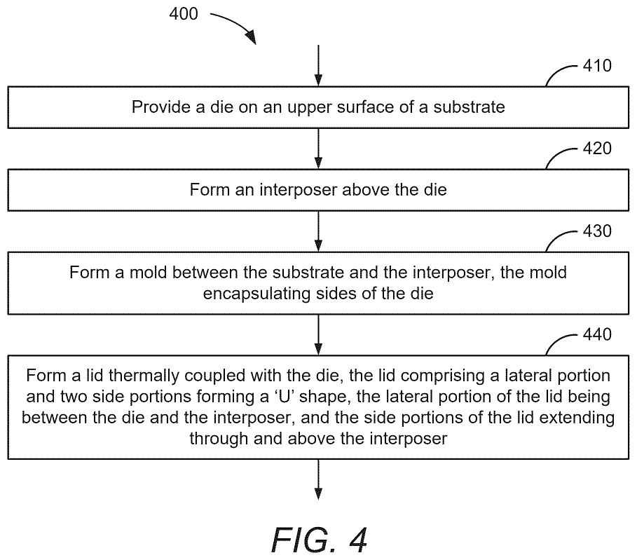

FIGS. 3A-3D illustrate examples of stages of fabricating a semiconductor package—such as the semiconductor package 200—in accordance with at one or more aspects of the disclosure.

FIG. 3A illustrates a stage in the (first) die 220 is provided on the substrate 210. In an aspect, this may be a part of a standard MEP process after non-conductive paste (NCP) curing and before substrate bonding.

FIG. 3B illustrates a stage in which the TIM 290 may be dispensed, and the lid 280 maybe attached.

FIG. 3C illustrates a stage in which the mold 230, the through-mold vias 260, and the interposer 240 may be formed. In an aspect, this may be a continuation of the MEP process including substrate bonding, FAM, bottom ball attached, etc.

FIG. 3D illustrates a stage in which the second die 250 may be provided on the upper surface of the interposer 240, and in which the heat sink 270 may be formed.

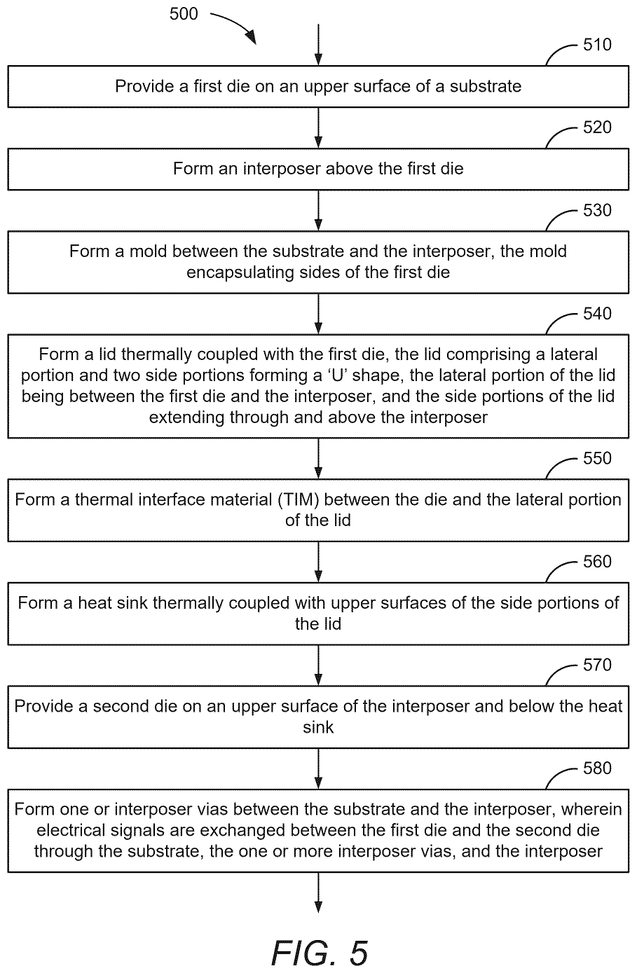

FIG. 4 illustrates a flow chart of an example method 400 of fabricating a semiconductor package, such as the semiconductor package 200, in accordance with at one or more aspects of the disclosure.

In block 410, a die 220 may be provided on an upper surface of a substrate 210.

In block 420, an interposer 240 may be formed above the die 220.

In block 430, a mold 230 may be formed between the substrate 210 and the interposer 240. The mold 230 may encapsulate sides of the die 220.

In block 440, a lid 280 may be formed. The lid 280 may be thermally coupled with the die 220, and may comprise a lateral portion and two side portions forming a ‘U’ shape. The lateral portion of the lid 280 may be between the die 220 and the interposer 240. The side portions of the lid 280 may extend through and above the interposer 240.

FIG. 5 illustrates a flow chart of an example method 500 of fabricating a semiconductor package, such as the semiconductor package 200 in accordance with at one or more aspects of the disclosure. FIG. 5 may be viewed as being more comprehensive than FIG. 4. In FIG. 5, second die 250 is mentioned. Hence, die 220 will be referred to as a first die 220.

Block 510 may be similar to block 410. That is, in block 510, a first die 220 may be provided on an upper surface of a substrate 210.

Block 520 may be similar to block 420. That is, in block 520, an interposer 240 may be formed above the first die 220.

Block 530 may be similar to block 430. That is, in block 530, a mold 230 may be formed between the substrate 210 and the interposer 240. The mold 230 may encapsulate sides of the first die 220.

Block 540 may be similar to block 440. That is, in block 540, a lid 280 may be formed. The lid 280 may be thermally coupled with the first die 220, and may comprise a lateral portion and two side portions forming a ‘U’ shape. The lateral portion of the lid 280 may be between the first die 220 and the interposer 240. The side portions of the lid 280 may extend through and above the interposer 240.

In block 550, a thermal interface material (TIM) 290 may be formed between the die 220 and the lateral portion of the lid 280.

In block 560, a heat sink 270 may be formed. The heat sink 270 may be thermally coupled with upper surfaces of the side portions of the lid 280.

In block 570, a second die 250 may be provided on an upper surface of the interposer 240 and below the heat sink 270.

In block 580, one or more through-mold vias 260 may be formed between the substrate 210 and the interposer 240. In this way, electrical signals may be exchanged between the first die 220 and the second die 250 through the substrate 210, the one or more through-mold vias 260, and the interposer 240.

The following should be noted regarding the flow indicated in FIGS. 4-5. Unless otherwise indicated, the flow of blocks do not necessarily limit the ordering in which the blocks may be performed. In other words, the blocks may be performed in any order that is logical.

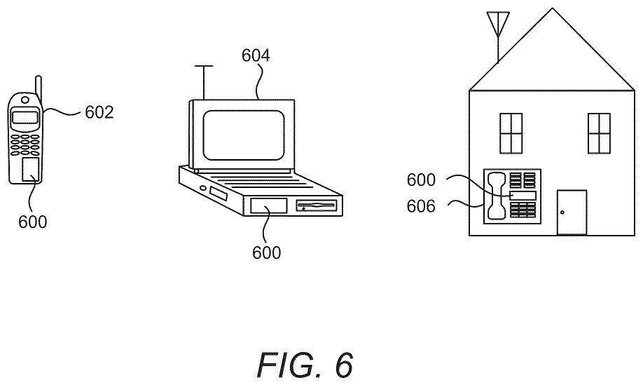

FIG. 6 illustrates various electronic devices 600 that may be integrated with any of the aforementioned semiconductor package in accordance with various aspects of the disclosure. For example, a mobile phone device 602, a laptop computer device 604, and a fixed location terminal device 606 may each be considered generally user equipment (UE) and may include one or more semiconductor packages (e.g., semiconductor package 200) as described herein. The devices 602, 604, 606 illustrated in FIG. 6 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor package, comprising: a die on an upper surface of a substrate; an interposer above the die; a mold between the substrate and the interposer, the mold encapsulating sides of the die; and a lid thermally coupled with the die, the lid comprising a lateral portion and two side portions forming a ‘U’ shape, the lateral portion of the lid being between the die and the interposer, and the side portions of the lid extending through and above the interposer.

Clause 2: The semiconductor package of clause 1, wherein the die is a system-on-chip (SoC) die.

Clause 3: The semiconductor package of any of clauses 1-2, a thermal interface material (TIM) between the die and the lateral portion of the lid.

Clause 4: The semiconductor package of clause 3, wherein an upper surface of the TIM is in direct contact with a lower surface of the lateral portion of the lid, or wherein a lower surface of the TIM is in direct contact with an upper surface of the die, or both.

Clause 5: The semiconductor package of any of clauses 3-4, wherein the TIM includes any one or more of tapes, greases, gels, adhesives, dielectric pads, phase change materials, and graphites.

Clause 6: The semiconductor package of any of clauses 1-5, further comprising: a heat sink thermally coupled with upper surfaces of the side portions of the lid.

Clause 7: The semiconductor package of clauses 6, wherein the heat sink is in direct contact with the upper surfaces of the side portions of the lid.

Clause 8: The semiconductor package of any of clauses 6-7, wherein the die is a first die, wherein the semiconductor package further comprises: a second die on an upper surface of the interposer and below the heat sink; and one or more through-mold vias between the substrate and the interposer, and wherein electrical signals are exchanged between the first die and the second die through the substrate, the one or more through-mold vias, and the interposer.

Clause 9: The semiconductor package of clause 8, wherein the second die is a memory die.

Clause 10: The semiconductor package of any of clauses 1-9, wherein the lid is formed from copper (Cu).

Clause 11: The semiconductor package of any of clauses 1-10, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 12: A method of fabricating a semiconductor package, the method comprising: providing a die on an upper surface of a substrate; forming an interposer above the die; forming a mold between the substrate and the interposer, the mold encapsulating sides of the die; and forming a lid thermally coupled with the die, the lid comprising a lateral portion and two side portions forming a ‘U’ shape, the lateral portion of the lid being between the die and the interposer, and the side portions of the lid extending through and above the interposer.

Clause 13: The method of clause 12, wherein the die is a system-on-chip (SoC) die.

Clause 14: The method of any of clauses 12-13, forming a thermal interface material (TIM) between the die and the lateral portion of the lid.

Clause 15: The method of clause 14, wherein an upper surface of the TIM is in direct contact with a lower surface of the lateral portion of the lid, or wherein a lower surface of the TIM is in direct contact with an upper surface of the die, or both.

Clause 16: The method of any of clauses 14-15, wherein the TIM includes any one or more of tapes, greases, gels, adhesives, dielectric pads, phase change materials, and graphites.

Clause 17: The method of any of clauses 12-16, further comprising: forming a heat sink thermally coupled with upper surfaces of the side portions of the lid.

Clause 18: The method of clauses 17, wherein the heat sink is in direct contact with the upper surfaces of the side portions of the lid.

Clause 19: The method of any of clauses 17-18, wherein the die is a first die, wherein the method further comprises: forming a second die on an upper surface of the interposer and below the heat sink; and forming one or more through-mold vias between the substrate and the interposer, and wherein electrical signals are exchanged between the first die and the second die through the substrate, the one or more through-mold vias, and the interposer.

Clause 20: The method of clause 19, wherein the second die is a memory die.

Clause 21: The method of any of clauses 12-20, wherein the lid is formed from copper (Cu).

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a die on an upper surface of a substrate;
an interposer above the die;
a mold between the substrate and the interposer, the mold encapsulating sides of the die; and
a lid thermally coupled with the die, the lid comprising a lateral portion and two side portions forming a ‘U’ shape, the lateral portion of the lid being between the die and the interposer, and the side portions of the lid extending through and above the interposer.

2. The semiconductor package of claim 1, wherein the die is a system-on-chip (SoC) die.

3. The semiconductor package of claim 1, further comprising:
a thermal interface material (TIM) between the die and the lateral portion of the lid.

4. The semiconductor package of claim 3,
wherein an upper surface of the TIM is in direct contact with a lower surface of the lateral portion of the lid, or
wherein a lower surface of the TIM is in direct contact with an upper surface of the die, or
both.

5. The semiconductor package of claim 3, wherein the TIM includes any one or more of tapes, greases, gels, adhesives, dielectric pads, phase change materials, and graphites.

6. The semiconductor package of claim 1, further comprising:
a heat sink thermally coupled with upper surfaces of the side portions of the lid.

7. The semiconductor package of claim 6, wherein the heat sink is in direct contact with the upper surfaces of the side portions of the lid.

8. The semiconductor package of claim 6,
wherein the die is a first die,
wherein the semiconductor package further comprises:
a second die on an upper surface of the interposer and below the heat sink; and
one or more through-mold vias between the substrate and the interposer, and
wherein electrical signals are exchanged between the first die and the second die through the substrate, the one or more through-mold vias, and the interposer.

9. The semiconductor package of claim 8, wherein the second die is a memory die.

10. The semiconductor package of claim 1, wherein the lid is formed from copper (Cu).

11. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor package, the method comprising:
providing a die on an upper surface of a substrate;
forming an interposer above the die;
forming a mold between the substrate and the interposer, the mold encapsulating sides of the die; and
forming a lid thermally coupled with the die, the lid comprising a lateral portion and two side portions forming a ‘U’ shape, the lateral portion of the lid being between the die and the interposer, and the side portions of the lid extending through and above the interposer.

13. The method of claim 12, wherein the die is a system-on-chip (SoC) die.

14. The method of claim 12, further comprising:
forming a thermal interface material (TIM) between the die and the lateral portion of the lid.

15. The method of claim 14,
wherein an upper surface of the TIM is in direct contact with a lower surface of the lateral portion of the lid, or
wherein a lower surface of the TIM is in direct contact with an upper surface of the die, or
both.

16. The method of claim 14, wherein the TIM includes any one or more of tapes, greases, gels, adhesives, dielectric pads, phase change materials, and graphites.

17. The method of claim 12, further comprising:
forming a heat sink thermally coupled with upper surfaces of the side portions of the lid.

18. The method of claim 17, wherein the heat sink is in direct contact with the upper surfaces of the side portions of the lid.

19. The method of claim 17,
wherein the die is a first die,
wherein the method further comprises:
provide a second die on an upper surface of the interposer and below the heat sink; and
forming one or more through-mold vias between the substrate and the interposer, and
wherein electrical signals are exchanged between the first die and the second die through the substrate, the one or more through-mold vias, and the interposer.

20. The method of claim 12, wherein the lid is formed from copper (Cu).
